(19) United States
(12) Patent Application Publication
(10) Pub. No.: US 2007/0209925 A1
(43) Pub. Date: Sep. 13, 2007

(54) Etch and sidewall selectivity in plasma sputtering

(75) Inventors: Xianmin Tang, San Jose, CA (US); Praburam Gopalraja, San Jose, CA (US); Jenn Yue Wang, Fremont, CA (US); Jick Yu, San Jose, CA (US)

Correspondence Address: LAW OFFICES OF CHARLES GUENZER;ATTN: APPLIED MATERIALS, INC., 2211 PARK BOULEVARD, P.O. BOX 60729, PALO ALTO, CA, 94306, US

(73) Assignee: Applied Materials, Inc., Santa Clara, CA (US)

(21) Appl. No.: 11/373,643

(22) Filed: Mar. 9, 2006

(51) Int. Cl. C23C 14/32

(52) U.S. Cl. 204/192.1; 204/192.32

(57) ABSTRACT

A substrate processing method practiced in a plasma sputter reactor including an RF coil and two or more coaxial electromagnets, at least two of which are wound at different radii. After a barrier layer, for example, of tantalum is sputter deposited into a via hole, the RF coil is powered to cause argon sputter etching of the barrier layer and the current to the electromagnets are adjusted to steer the argon ions, for example to eliminate sidewall asymmetry. For example, the two electromagnets are powered with unequal currents of opposite polarities or a third electromagnet wrapped at a different height is powered. In one embodiment, the steering straightens the trajectories near the wafer edge. In another embodiment, the etching is divided into two steps in which the steering inclines the trajectories at opposite angles. The invention may also be applied to other materials, such as copper.

### FIELD OF THE INVENTION

The invention relates generally to plasma sputtering. In particular, the invention relates to auxiliary magnetic fields enhancing different phases of a sputtering deposition process.

### BACKGROUND ART

Sputtering, alternatively called physical vapor deposition (PVD), is the preferred method of depositing layers of metals and related materials in the fabrication of semiconductor integrated circuits. The preference arises mostly from its relatively low cost and relatively high deposition rate. However, advanced integrated circuits include surface features such as via holes which are narrow and deep, that is, having high aspect ratios. Sputtering is fundamentally a ballistic process ill suited to coat the sidewalls and bottom of a high-aspect hole. However, sputtering processes have been developed which have allowed sputtered coatings of fair uniformity into such holes. These processes rely upon ionizing sputter particles and electrostatically attracting the ions deep within the holes.

Such processes have been long known but the increasing aspect ratios and decreasing film thickness required in advanced circuitry have prompted more complex sputtering chambers. One such sputter reactor is the EnCoRe II Ta(N) chamber available from Applied Materials, Inc. of Santa Clara, Calif. Gung et al. (hereafter Gung) have described a version of this sputtering chamber and associated processes in U.S. patent application Ser. No. 11/119,350 (hereafter Gung), now published as U.S. Patent Application Publication 2005/0263389, incorporated herein by reference.

Such a magnetron sputter reactor 8, illustrated schematically in cross section in FIG. 1, can effectively sputter thin films of Ta and TaN into holes having high aspect ratios and can further act to plasma clean the substrate and selectively etch portions of the deposited tantalum-based films. The reactor 8 includes a vacuum chamber 10 including sidewalls 12 arranged generally symmetrically about a central axis 14. A vacuum pump system 16 pumps the vacuum chamber 10 to a very low base pressure in the range of 10⁻⁶ Torr or below. However, a gas source 18 connected to the chamber through a mass flow controller 20 supplies argon into the vacuum chamber 10 as a sputter working gas. The vacuum pump system 16 typically maintains an argon pressure inside the chamber 10 in the low milliTorr range. A second gas source 22 supplies nitrogen gas into the chamber through another mass flow controller 24 when tantalum nitride is being deposited.

A pedestal 30 arranged about the central axis 14 holds a wafer 32 or other substrate to be sputter coated. An unillustrated clamp ring or electrostatic chuck may be used to hold the wafer 32 to the pedestal 30. An RF power supply 34 supplying electrical power (referred to as RF bias power) preferably in the low megahertz range is connected through a capacitive coupling circuit 35 to the pedestal 30, which is conductive and acts as an electrode. In the presence of a plasma, the RF biased pedestal 30 develops a negative DC bias, which is effective at attracting and accelerating positive ions in the plasma. An electrically grounded shield 36 protects the chamber walls and the sides of the pedestal 30 from sputter deposition. Other shield configurations are possible. A target 38 is arranged in opposition to the pedestal 30 and is vacuum sealed to the chamber 10 through an isolator 40. At least the front surface of the target 38 is composed of a metallic material to be deposited on the wafer 32, which in this embodiment is tantalum.

A DC power supply 42 electrically biases the target 38 to a negative voltage with respect to the grounded shield 36 to cause the argon to discharge into a plasma such that the positively charged argon ions are attracted to the negatively biased target 38 and sputter tantalum from it. Some of the sputtered tantalum falls upon the wafer 32 and deposits a layer of the tantalum target material on it. In reactive sputtering, nitrogen gas is additionally admitted from the nitrogen source 18 into the chamber 10 to react with the tantalum being sputtered to cause the deposition of a tantalum nitride layer on the wafer 32.

The reactor 8 additionally includes an inductive coil 44, preferably having one wide turn wrapped around the central axis 14 just inside of the grounded shield 36 and positioned above the pedestal 30 approximately one-third of the distance to the target 38. The coil 44 is supported on the grounded shield 36 or another inner tubular shield but electrically isolated from it, and an electrical lead penetrates the sidewalls of the shield 36 and chamber 10 to power the RF coil 44. Preferably, the coil 44 is composed of the same barrier material as the target 38. An RF power supply 46 applies RF current to the coil 44 to induce an axial RF magnetic field within the chamber and hence generate an azimuthal RF electric field that is very effective at coupling power into the plasma and increasing its density. The RF power inductively coupled into the vacuum chamber 10 through the RF coil 44 may be used as the primary plasma power source when the target power is turned off and the sputter reactor is being used to etch the wafer 32 with argon ions or for other purposes. The inductively coup led RF power may alternatively act to increase the density of the plasma primarily generated by the DC powered target 38 and extending towards the pedestal 30.

The coil 44 may be relatively tall and be composed of the target material, for example, tantalum in the described embodiment, to act as a secondary sputtering target under the proper conditions.

A DC power supply 48 is also connected to the RF coil 44 to apply a DC voltage to it to better control its sputtering. The illustrated parallel connection of the coil RF supply 46 and the coil DC supply 48 is functional only. They may be connected in series. Alternatively, they may be connected in parallel with respective coupling and filtering circuits to allow selective imposition of both RF and DC power, for example a capacitive circuit in series with the RF power supply 46 and an inductive circuit in series with the DC power supply 48. A single coil power supply can be designed for both types of power.

The target sputtering rate and sputter ionization fraction of the sputtered atoms can be greatly increased by placing a magnetron 50 is back of the target 38. The magnetron 50 preferably is small, strong, and unbalanced. The smallness and strength increase the ionization fraction and the imbalance causes a magnetic field to project into the processing region towards the pedestal 30. Such a magnetron includes an inner pole 52 of one magnetic polarity along the central axis and an outer pole 54 which surrounds the inner pole 52 and has the opposite magnetic polarity. The magnetic field extending between the poles 52, 54 in front of the target 38 creates a high-density plasma region 56 adjacent the front face of the target 46, which greatly increases the sputtering rate. The magnetron 50 is unbalanced in the sense that the total magnetic intensity of the outer pole 54, that is, the magnetic flux integrated over its area, is substantially greater than that of the inner pole, for example, by a factor of two or more. The unbalanced magnetic field projects from the target 38 toward the wafer 32 to extend the plasma and to guide sputtered ions to the wafer 32 and reduce plasma diffusion to the sides.

To provide a more uniform target sputtering pattern, the magnetron 50 is typically formed in a triangular or a closed and generally azimuthally arced shape that is asymmetrical about the central axis 14. However, a motor 60 drives a rotary shaft 62 extending along the central axis 14 and fixed to a plate 66 supporting the magnetic poles 52, 54 to rotate the magnetron 40 about the central axis 40 and produce an azimuthally uniform time-averaged magnetic field. The arc-shaped magnetron disposed closer to the target periphery is often used if sputtering from the edge of the target is to be emphasized. If the magnetic poles 52, 54 are formed by respective arrays of opposed cylindrical permanent magnets, the plate 66 is advantageously formed of a magnetic material such as magnetically soft stainless steel to serve as a magnetic yoke magnetically coupling the backs of the two poles 52, 54. Magnetron systems are known in which the radial position of the magnetron, especially an arc-shaped one, can be varied between different phases of the sputtering process and chamber cleaning as described by Gung et al. in U.S. patent application Ser. No. 10/949,735, filed Sep. 23, 2004 and published as U.S. Application Publication 2005/0211548 and by Miller et al. in U.S. patent application Ser. No. 11/226,858, filed Sep. 14, 2005, both incorporated herein by reference in their entireties.

Great flexibility is afforded by a quadruple electromagnet array 72 positioned generally in back of the RF coil 44. The quadruple electromagnet array 72 includes four solenoidal coils 74, 76, 78, 80 wrapped generally circularly symmetrically about the central axis 14 of the reactor 70. The coils 74, 76, 78, 80 are preferably arranged in a two-dimensional array annularly extending around the central axis. The nomenclature is adopted of the top inner magnet (TIM) 74, top outer magnet (TOM) 76, bottom inner magnet (BIM) 78, and bottom outer magnet (BOM) 80. The coils 74, 76, 78, 80 may each be separately powered, for example, by respective variable DC current supplies 82, 84, 86, 88, preferably bipolar DC supplies. Corresponding unillustrated grounds or return paths are connected to the other ends of the multi-wrap coils 74, 76, 78, 80. However, in the most general case, not all coils 74, 76, 78, 80 need be connected to a common ground or other common potential. Other wiring patterns are possible. All coils 74, 76, 78, 80 have at least one and preferably two end connections that are readily accessible on the exterior of the assembled chamber to allow connection to separate power supplies or other current paths and to allow easy reconfiguration of these connections, thereby greatly increasing the flexibility of configuring the chamber during development or for different applications. In production, it is possible that the number of current supplies 82, 84, 86, 88 may be reduced but the capability remains to selectively and separately power the four different coils 74, 76, 78, 80, preferably with selected polarities, if the need arises as the process changes for the sputter reactor 8.

The eight wires of the four coils 74, 76, 78, 80 may be connected directly or through a connection board to one or more power supplies 82, 84, 86, 88. An operator can manually reconfigure the connection scheme with jumper cables between selected pairs of terminals without disassembling either the coil array 72 or the vacuum chamber 10. It is possible also to use, electronically controlled switches for the different configurations. During operational use once a process recipe has been established, the number of active coils and power supplies may be reduced. Further, current splitters and combiners and serial (parallel and anti-parallel) connections of coils can be used once the general process regime has been established.

A controller 92 contains a memory 94, which may be a removable recorded magnetic or optical disk, memory stick, or other similar memory means, which is loaded with a single- or multi-step process recipe for achieving a desired structure in the wafer 32. The controller 92 accordingly controls the process control elements, for example, the vacuum system 16, the process gas mass flow controllers 20, 24, the wafer bias supply 34, the target power supply 42, the RF and DC coil supplies 48, 49, the magnetron motor 60 to control its rotation rate and hence the position of the magnetron, and the four electromagnet current supplies 82, 84, 86, 88.

Gung discloses a process recipe for depositing a Ta/TaN barrier including a sputter etch step in which the RF coil 46 provides the principal plasma power in generating argon ions which sputter etch the wafer 32 and remove especially the TaN at the bottoms of the holes. The disclosed recipe is effective at providing a uniform flux of both sputter deposition atoms and sputtering etching ions. However, it has been discovered that the recipe is subject to various problems that are exacerbated by the adoption of soft low-k dielectric materials.

In the recent past, the dielectric layers have composed principally of silicon dioxide (silica) perhaps with some fluorine doping. After the dielectric layer has been patterned and etched to form a interconnect hole through it, particularly a dual-damascene structure to be described later, a barrier layer, for example, of Ta/TaN is coated on the walls of the hole to prevent the after filled copper from diffusing into the dielectric. However, it is generally desired to remove the barrier layer from the bottom of the interconnect hole to reduce contact resist. Silica dielectrics are relatively hard and stable, and it was previously considered acceptable to temporarily expose the silica dielectric before then reapplying a thin tantalum layer in a final flash deposition step. The hard silica is not greatly affected by small amounts of sputter etching.

However, very advanced integrated circuits are using dielectric layers of lower dielectric constant (low-k dielectrics). The reduced dielectric constant provided by fluorine-doped silica is no longer sufficient. Instead, carbon-containing low-k dielectrics have been developed. Some of the lowest-k materials, such as Black Diamond II developed by Applied Materials and described by Li et al. in U.S. Patent Application Publication 2003/0194495, use porous materials of relatively high carbon content and having a porosity near 30% to achieve dielectric constants below 2.5. Such porous carbon-based materials are very soft. Other low-k dielectrics are available having a substantial carbon content and are sometimes characterized as organic or polymeric dielectrics. These materials include Silk® and Cyclotene® (benzocyclobutene) dielectric materials available from Dow Chemical. We have observed that the previously available sputter/etch processes for selectively depositing barrier layers cause problems when the barrier layer is being coated on a soft low-k dielectric material.

### SUMMARY OF THE INVENTION

An etching process performed in a plasma sputter reactor in which two or more electromagnets steer argon ions to strike the wafer at controlled angles. The invention is particularly useful for reducing sidewall asymmetry and protecting soft low-k dielectric materials in inter-level interconnects. The etching may be performed after the liner layer, for example, of a barrier layer is deposited on the walls and bottom of a hole such as a via hole in a dual-damascene interconnect structure.

The steering may be effected by two supplying different magnitudes of opposed DC currents to two co-planar coaxial magnetic coils or by powering three or more coils, at least two of which are is in different planes with respect to the chamber central axis.

In another aspect of the invention, the etching is divided into two phases in which the argon ions are steered to strike the wafer at opposed angles.

Another aspect of the invention includes selectively etching copper relative to a tantalum or tungsten barrier over a dielectric for copper metallization by reducing the argon ion energy, that is, the pedestal self-bias voltage, to less than 65 eV. In a two step process, the barrier is opened at the via bottom by initially using a significantly higher argon ion energy to expose the copper there. Then the argon ion energy is reduced.

### BRIEF DESCRIPTION OF THE DRAWINGS

FIG. 1 is a cross-sectional view of sputter reactor usable with the invention.

FIG. 2 is a cross-sectional view of an inter-level, dual-damascene structure.

FIG. 3 is a graph of the dependence of deposition upon RF bias power.

FIG. 4 is a graph of the structural etch selectivity of different portions of a dual-damascene structure.

FIG. 5 is a graph of the etching rate as a function of RF bias power.

FIG. 6 is a graph of etch selectivity as a function of electrical power for electrical elements in the sputter reactor of FIG. 1.

FIG. 7 is a graph of the target power optimized for etch selectivity.

FIG. 8 is a graph of sputtering yield and material selectivity as a function of ion energy according to another aspect of the invention.

FIG. 9 is a cross-sectional view of an ideal dual-damascene structure.

FIG. 10 is a cross-sectional view of a sputter etching pattern observed with a known sputter deposition and etching process used in forming a barrier layer in the dual-damascene structure.

FIG. 11 a is cross-sectional view of a sputter etching pattern achievable with the invention.

FIG. 12 is a cross-sectional view of a sputtering etching pattern also achievable with the invention.

FIG. 13 is a schematic diagram of an auxiliary magnetic field distribution of the prior art.

FIG. 14 is a schematic diagram of an auxiliary magnetic field distribution of one aspect of the invention.

FIGS. 15 and 17 are two schematic representations of the steering of the magnetic null provided by an aspect of the invention.

FIGS. 16 and 18 are schematic cross-sectional view of the effect of the steering of FIGS. 15 and 17 respectively upon ion incidence angle within a via.

### DETAILED DESCRIPTION OF THE PREFERRED EMBODIMENTS

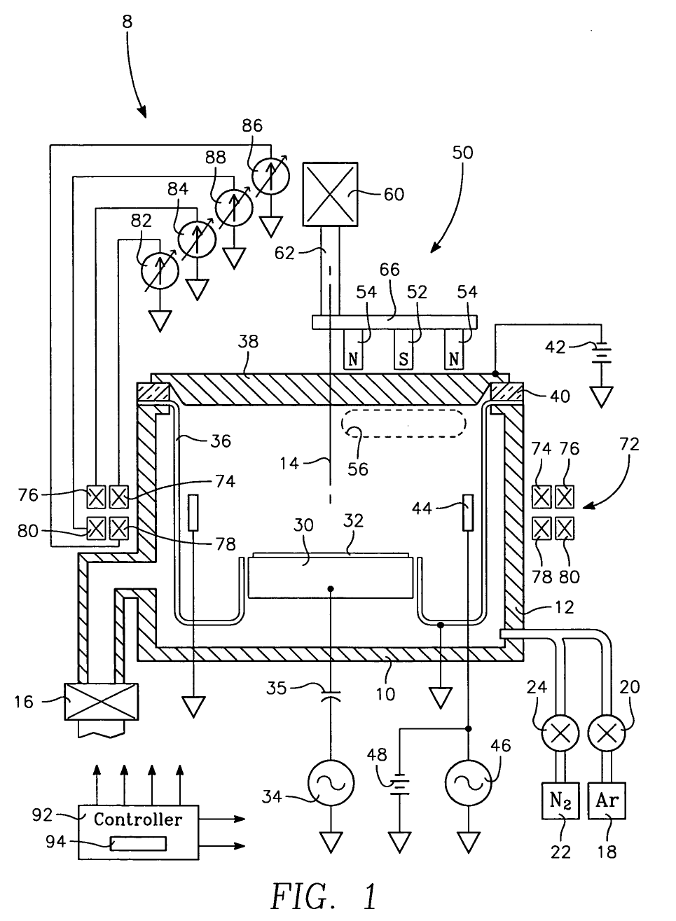

The EnCoRe II reactor 8 of FIG. 1 can be operated not only in a sputter deposition mode but also in a sputter etch mode in which material already deposited on the wafer can be etched away. Alternatively, operating conditions may be selected such that the sputter deposition and sputter etching are being simultaneously performed to effect selective deposition at different areas of the interconnect structure. However, the previous recipes to sputter deposit and etch harder dielectric materials cause problems when applied to soft, porous low-k materials, such as the previously discussed Black Diamond II or other soft dielectric materials. Any sputter etching of the soft low-k dielectric collapses the pores, introduces impurities into the dielectric, and increases the dielectric constant. Generally, carbon-doped silica is softer than silicon dioxide. As a result, it is now desired to never expose the low-k dielectric layer during the deposition and selective etching of the barrier layer. The deposition and selective etching recipe disclosed by Gung suffers at least two problems when applied to soft low-k dielectrics, specifically poor selectivity between via bottom and trench floor and sidewall asymmetry. The conventional recipes developed for silica dielectrics circumvented these problems by temporarily exposing the dielectric to the energetic sputter etching ions before a final flash deposition step. However, sputter etching of the soft low-k dielectric tends to degrade low-k dielectric materials. Gung's recipes are not adequate for soft low-k dielectrics, which need to be protected from sputter etching. The two effects of selectivity between trench and via and sidewall asymmetry need to be separately addressed to better protect the low-k dielectric.

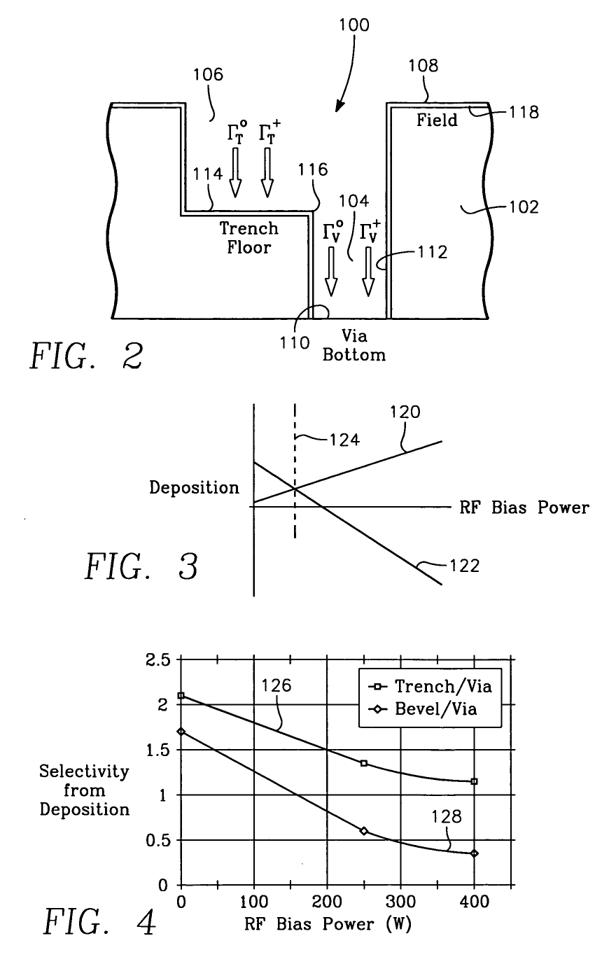

The selectivity will be addressed first. One dual-damascene structure 100 is illustrated in the cross-sectional view of FIG. 2. A complex dual-damascene hole etched in a dielectric layer 102 includes a narrow via 104 at the bottom connected to a wider trench 106 at the top. Important parts of the structure include a planar field region 108 on top of the dielectric layer 102, a via bottom 110 at the bottom of the via 104, via sidewalls 112, a trench floor 114, and a bevel 116 at the corner of the trench floor 114 and the via 104. The vertically patterned dual-damascene structure 100 may be obtained by an unillustrated etch stop layer within the dielectric layer 102 at a level near the trench floor 114. Copper, which is the preferred metallization, is filled in a single step into both the via 104 and the trench 106 to form a vertical interconnect through the via 104 to a conductive feature in the underlying layer and to also form a horizontal interconnect along the trench 106 to other vias and the like. However, copper tends to diffuse into the dielectric layer 102 and short it out. Accordingly, a barrier layer 118, for example, a Ta/TaN bilayer, is coated preferably by sputtering onto the walls and surfaces of the dual-damascene structure including the field region 108 before the hole is filled and overfilled with copper in an electroplating process. However, it is preferred that the barrier layer 118 not form on or at least be much thinner on the via bottom 110 to reduce the contact resistance to the underlying conductive feature. But, the barrier layer 118 needs to remain in the trench floor 114 and the via sidewalls 112 and preferably should remain on the field region 108. The trench floor 114 and its bevel 116 present the greatest challenge in selectivity to the via bottom. If extended sputter etching is used to remove the Ta or TaN deposited on the via bottom 110, the etching is likely to expose the low-k dielectric on the trench floor 114 and to roughen and quickly remove the soft dielectric. High-energy sputter etching will also collapse the pores in the remaining dielectric.

The desired selectivity of a thicker barrier layer 118 on the trench floor 114 and a thinner or non-existent barrier layer 118 on the via bottom 110 can be achieved either by preferentially depositing less barrier material at the via bottom 110 or by etching more barrier material from there. Gung describes the formation of such a patterned barrier layer 118 in the sputter chamber 8 of FIG. 1.

To minimize removal of the barrier layer 118 on the trench floor 114 while completely removing it at the via bottom 110, it is desired to maximize the etch selectivity ζ between the via bottom and the trench floor, specifically:

$$ζ = \frac{{ER}_{V}}{{ER}_{T}} ,$$

where ER_{V} is the etch rate at the via bottom and ER_{T} is the etch rate at the trench floor. The trench etch rate with reference to FIG. 2 can be expressed as
ER_{T} =η₀·T⁺_{T}−T⁰_{T},
where η₀(E) is the energy dependent ion sputtering yield, T_{T}⁺ is the ion flux on the trench floor, and T_{T}⁰ is the neutral flux on the trench floor. The second term represents a deposition of low energy neutral metal atoms. Similarly, the via etch rate can be expressed as
ER_{V}=η₀(E)·T_{V}⁺−T_{V}⁰−δ·η₀(E)·T_{V}⁺,
where T_{V}⁺ is the ion flux at the via bottom, T_{V}⁰ is the neutral flux at the via bottom, and δ is the recapture coefficient of resputtered materials at the via bottom, which depends upon the structure of the via.

High etch selectivity can be achieved if the neutral flux on the trench floor is much greater than that at the via bottom
T⁰_{T>>T}⁰_{V}
or the ion flux on the trench floor is much less than that at the via bottom.
T⁺_{T<<T}⁺_{V}.
All these fluxes represent the fluxes that reach the respective surfaces so that the angular distributions of the neutrals and ions play a role in achieving the desired selectivity.

A related phenomenon is the etch rate of the bevel area of the trench floor associated with the facets that develop next to the etched vias. The sputter etch rate of the bevels from high-energy ions is generally higher than that of the trench floor because of the exposed geometry of the corner while the neutral deposition rate at the corner is generally no higher than that at the trench floor. On the other hand, the area of the developed facets is considerably less than the area of the trench floor so that a change of dielectric constant at the bevel resulting from the dielectric being temporarily exposed there may not be a severe problem.

For a conventional diode sputter reactor without auxiliary magnets or supplemental RF inductive power, high selectivity requires optimizing the DC power applied to the target, the RF bias power applied to the pedestal electrode, and chamber pressure. It is believed that the conventional diode sputter reactor does not afford sufficient control. However, the additional inductively coupled RF power available in the reactor 8 of FIG. 1 allows the DC sputtering power to be separated from the RF generation of etching plasma.

Selectivity can alternatively be achieved through deposition selectivity. The graph of FIG. 3 schematically illustrates dependence of net deposition or coverage in the sputter deposition stage upon RF bias power. Plot 120 for net deposition at the via bottom shows that increasing RF bias power draws the ionized sputter particles deep within the via and hence shows deposition increasing from a small value at zero biasing arising from the small fraction of neutral sputter particle that find their way to the via bottom. On the other hand, plot 122 shows that net deposition at the bevel is relatively high at zero bias from the neutral and generally isotropic neutral sputter particles but increasing bias increases the energy of the ionized sputter particles and hence increases the sputter etching of the bevel, thus decreasing the net deposition. At relatively high bias, the sputter etching dominates the sputter deposition and facets are formed. At a crossover RF bias point 124, the via bottom coverage 120 equals the bevel coverage 122. A region of high bevel/via deposition selectivity exists below the crossover RF bias point 124.

The graph of FIG. 4 shows the deposition selectivity as a function of the RF bias power in watts for a 300 mm wafer. The trench/via deposition selectivity shown in plot 126 is always greater than the bevel/via deposition selectivity shown in plot 128. Hence, deposition selectivity resulting from both neutrals and ions is always smaller at the bevel than at the trench floor.

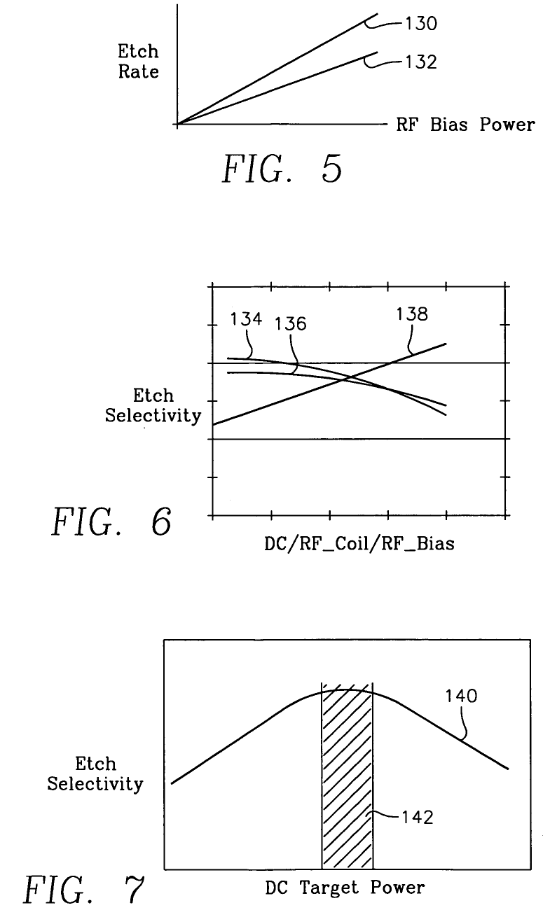

The graph of FIG. 5 shows the dependence of etch rate upon RF bias power in the sputter etch stage, for example, relying principally upon argon ion sputter etching of the wafer. Plot 130 shows the etch rate at the bevel and plot 132 shows it at the via bottom. Because of the geometry, the bevel etch rate tends to always be greater than the via bottom etch rate. Thus, RF biasing provides no advantageous etch selectivity of via bottom over bevel.

The EnCoRe II chamber of FIG. 1 provides additional controls to adjust the selectivity, in particular, the RF power applied to the RF coil. The DC power applied to the RF coil and the DC magnetic field from the quadruple electromagnet array provide added flexibility, but deposition or etch selectivity is not a primary effect. The graph of FIG. 6 schematically shows the dependence of etch selectivity upon power applied to the target, RF coil, and pedestal. Plot 134 shows the etch selectivity initially slowly decreases with increasing RF bias but then more rapidly decreases. Plot 136 shows a similar behavior for the etch selectivity as a function of RF power applied to the RF coil. However, plot 138 shows a strong nearly linear increase of etch selectivity with increasing DC target power. As a result, DC power is the most effective control but it must be combined with optimized RF coil power and RF bias. The graph of FIG. 7 in plot 140 shows an overall etch selectivity as a function of DC target power in combination with associated RF bias and RF coil power. A region 142 near the peak of the overall etch selectivity is the optimum region for operation.

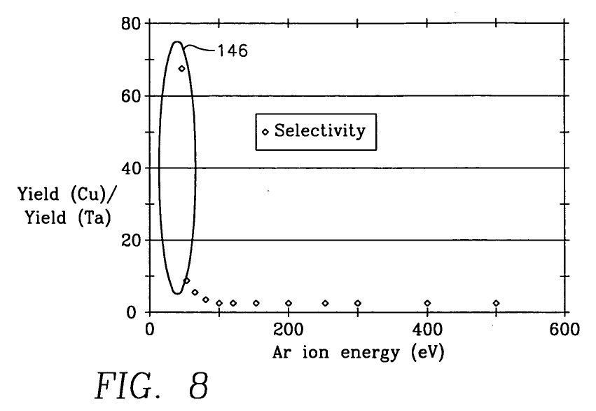

The etch selectivity can also be improved by increasing the material selectivity of energetic argon ions. As illustrated in the plot of points of FIG. 8, argon ions sputter copper and tantalum with different yields. At low argon ion energies, the selectivity for sputtering copper over tantalum greatly increases. In a region 146 below about 65 eV, the selectivity greatly increases. Thus under the proper conditions, copper is etched but tantalum is effectively not etched. The process is particularly useful in a two-step process in which the tantalum is opened at the via bottom in a conventional tantalum sputter etch and then the operating conditions are switched to selectively etch copper relative to tantalum. There are two recipes for achieving the low argon energies during the etch phase. In the first recipe, the RF coil power is 2 kW and the RF pedestal bias power is 250 W. In the second recipe, the DC target power is 4 kW, the RF coil power is 2 kW, the RF pedestal bias power is 700 W, and the DC coil power is 750 W. The same selectivity can be achieved for a tungsten-based barrier for copper metallization.

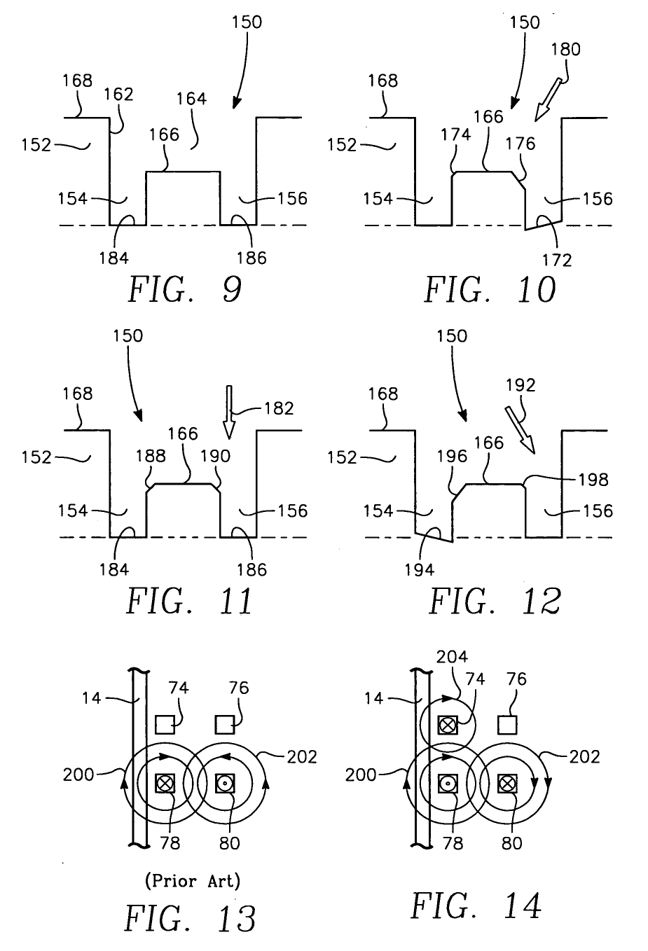

Sidewall asymmetry presents different problems than etch and deposition selectivity, which problems may be addressed in different ways in the EnCoRe II reactor. A dual-damascene structure 150 illustrated in the cross-sectional view of FIG. 9 represents the ideal structure produced in the dielectric etch phase and is consistent with the structure 100 of FIG. 2. The dual damascene structure 150 is formed through a dielectric layer 152 and includes vias 154, 156 with respective via bottoms 158, 160 overlying conductive features in the dielectric layer below. At least some via sidewalls 162 present very high aspect-ratio steps. The vias 154, 156 are interconnected by a long and A relatively wide trench 164 having a trench floor 166. The complex via structure 150 may be etched by various well known methods, for example, including two photolithographic steps dependent upon an intermediate etch stop layer formed in the dielectric layer 152 coincident with the trench floor 162. The entire via structure 150 including the vias 154, 156 and the trench 164 may be filled with copper in a single sequence of sputter depositing a thin copper seed layer and electroplating copper to fill the via structure 150 followed by chemical mechanical polishing (CMP) to remove excess copper outside the dual-damascene structure 164 over a field region 168 on top of the dielectric layer 152. Thereby, within the dielectric layer 152 are formed both a vertical interconnect structure through the vias 154, 156 and a horizontal interconnect structure through the trench 164.

An unillustrated barrier layer, for example of Ta or Ta/TaN, needs to be coated onto the surfaces of the dual-damascene structure before the copper to prevent the copper from diffusing into the dielectric and shorting it. Although the barrier layer, especially its nitride portion, is advantageously removed from the via bottoms 158, 160, the barrier is important on the via sidewalls 162, the trench floor 166 and the field region area 168 on top of the dielectric layer 152 outside of the dual-damascene structure 150.

The recipe disclosed by Gung for selectively forming barrier layers in different portions of the dual-damascene structure 150 by balancing sputter deposition and sputter etching exhibits good center-to-edge uniformity but it has been observed to introduce sidewall asymmetry and differential etching, particularly in the dual-damascene holes nearer the edge of the wafer. To ensure that all barrier nitride is removed from the near-edge via 156, it becomes necessary to increase the etch time, that is, to aggressively etch or over etch. As illustrated in the cross-sectional view of FIG. 10, the via hole 156 nearer the wafer edge develops a sloped bottom 172 during the over etch of the sputter etch step, which is used to remove the last of the barrier nitride there. The over etch into the underlying conductive feature at the via bottom 172 is itself not a great problem. However, the over etching also tends to remove the last of the barrier layer from the trench floor 166 and from the field area 168, thus exposing the underlying low-k dielectric layer. Also, facets 174, 176 (also called bevels) tend to form on the sides of trench floor 164 because of the exposed geometry at the corners. Some faceting is nearly inevitable, but its extent needs to be controlled. However, it has been observed that the near-edge facet 176 becomes relatively large. As the near-edge facet 176 proceeds down the near-edge via 156, the critical dimension (CD) is significantly affected as the via 156 is widened at its top by the tapering. It is thus seen that sidewall asymmetry becomes a problem that may eclipse radial non-uniformity as needing to be minimized. At least, sidewall asymmetry needs to be considered as well as radial non-uniformity.

The most exposed portion of the low-k dielectric layer 152 is that at the trench floor 166, which needs to remain covered by the barrier layer for the copper later deposited over it. On the other hand, the barrier layer at the via bottoms is advantageously removed to reduce contact resistance. The conventional recipes, however, have been observed to also remove the barrier layer on the trench floor 114 and to roughen the surface of the low-k dielectric there. Thus, it is desired to eliminate the liner at the via bottom 172 while leaving it on the trench floor 166.

The sidewall asymmetry exhibited in FIG. 10 can be explained in terms of the directionality of the sputter ions, particularly the argon sputter ions used in the sputter etch step. If the sidewall electromagnet array 72 of FIG. 1 is used principally to confine the sputter ions to a central area, the ions below the electromagnet array 72 tend to follow a path along an inward direction 180. The inwardly directed energetic ions preferentially etch the far, inward corner of the bottom of the near-edge via 156 to produce the sloping via bottom 172. They also tend to preferentially etch the near-edge facet 176.

In one aspect of the invention, it is desired to assure that the sputter etching ions reach the dual damascene structure 150 with a direction 182, shown in the cross-sectional view of FIG. 11, that is nearly perpendicular to the surface of the wafer to produce flat via bottoms 184, 186 and equally sized facets 188, 190.

On the other hand, at least in some cases, it desired to not overly compensate and cause the ions to approach with a direction 192, illustrated in the cross-sectional view of FIG. 12, pointing outwardly towards the wafer edge, thereby producing a sidewall asymmetry complementary to that of FIG. 10 with a sloping bottom 194 in the near-center via 152 and a large near-center facet 196 and a smaller near-edge facet 198.

As discussed in the background section, the electromagnet array 72 of FIG. 1 is composed of a top inner magnet (TIM) 74, a top outer magnet (TOM) 76, a bottom inner magnet (BIM) 78, and a bottom outer magnet (BOM) 80. Their driving currents may be represented by the vector TIM/TOM/BIM/BOM. The etch step disclosed by Gung applies equal and opposite currents to the bottom electromagnets 78, 80, specifically currents 0/0/19/−19, to produce the magnetic field distributions 200, 202 shown in FIG. 13. These field distributions may be characterized as either two opposed magnetic dipole fields located at the same axial height but having different radii or two opposed toroidal fields of different radii. The resultant total field falls very quickly inside the chamber sidewall 12 and effectively prevents the plasma and its ions from leaking to the chamber sidewall 12 or its shield 36, thus confining the plasma and its ions within the chamber with a fairly uniform plasma density. However, the strong and sharply focused repelling magnetic field is believed to introduce an inward directional component to the ions.

In one embodiment of the invention, a reduced level of current is applied to the top inner electromagnet 74 to produce the magnetic fields shown in FIG. 14 including the prior-art fields 200, 202 and an additional toroidal magnetic field distribution 204. In an example, the TIM current is counter-rotating with respect to the BIM current with a current vector of −1.25/0/19/−19. As noted above, the values of current do not directly represent the strength of the magnetic fields they produce because the bottom electromagnets 78, 80 have about twice as many turns as the top electromagnets 74, 76. The field added by the TIM electromagnet 74 produces the additional magnetic dipole field 204 at a different height than the dipole fields of the BIM and BOM electromagnets 78, 80 but the simple dipole field of the TIM electromagnet 74 falls off more slowly inside the chamber wall 12 than does the vector sum of the anti-parallel dipole fields of the BIM and BOM electromagnets 78, 80. The total magnetic field is not so sharply peaked along the direction of the central axis 14 near the chamber wall 12 or its shield 36.

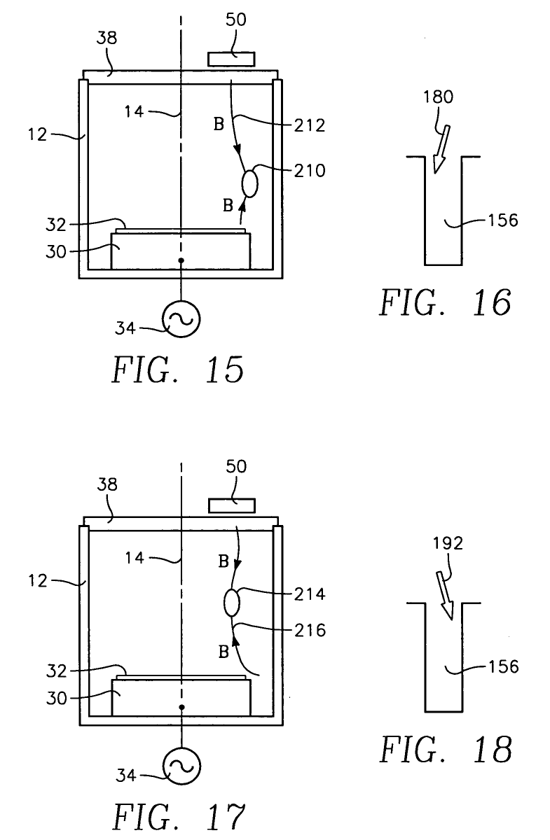

Furthermore, the directionality of the ions is greatly affected by the location of a magnetic null 210, illustrated in FIG. 15 in a distribution 212 of the magnetic field B produced by the sum of the magnetic means, including the electromagnet array 72 and the small rotating magnetron 50. If the null 210 is fairly low along the chamber wall 12, as in FIG. 15, the magnetic field tapers outwardly from the edge of the wafer 32, which causes incident ions, as illustrated in the cross-sectional view of FIG. 16, to be inclined inwardly along the direction 180 as they strike via 156 at the wafer edge. Such an effect can be generated by Gung's electromagnet currents of 0/0/19/−19. On the other hand, as illustrated in FIG. 17, if a magnetic null 214 formed by a distribution 216 of magnetic field B is higher along the chamber 12 wall, the distribution 216 tapers inwardly from the edge of the wafer 32, which causes the incident ions, as illustrated in the cross-sectional view of FIG. 18, to be inclined outwardly along the direction 192. Such a magnetic field distribution 216 can be produced by a combination of TIM/BIM/BOM currents or TOM/BIM/BOM currents or by unbalancing the BIM/BOM currents.

Thereby, the null may be steered by the multipolar magnetic field having coils displaced along the chamber axis 14. Therefore, the directionality introduced into the plasma ions may controlled and reduced in the direction of the perpendicular incidence of FIG. 4 to thereby reduce the sidewall asymmetry.

A recipe for the combined sputter deposition and sputter etch of a tantalum liner including ranges is summarized in TABLE 1.

TABLE 1

| | Ta | Etch | Flash |
|---|---|---|---|
| Time (s) | | | |
| DC Power (kW) | 15-40 | 0-5 | 15-40 |
| Bias Power (kW) | 0-0.8 | 0.3-1 | 0-0.8 |
| RF Coil Power (kW) | 0 | 1-2.5 | 0 |
| DC Coil Power (kW) | 0 | 0-1 | 0 |
| TIM Curr. (A) | 0 | −1-(−3) | 0 |
| TOM Curr. (A) | 0 | 0 | 0 |
| BIM Curr. (A) | 19 | 15-21 | 19 |
| BOM Curr. (A) | −19 | −15-(−21) | −19 |
| Ar (sccm) | 4 | 10 | 4 |
| Magnet Position | OUT | OUT | OUT |

The power levels should be normalized to a 300 mm wafer. It is understood that the polarities of the electromagnet currents refer to the direction of currents around the central axis 14 about which the electromagnetic coils are wrapped. This recipe is based on a single barrier layer of Ta. Another step in which nitrogen is additionally admitted into the chamber while tantalum is being sputtered enables the fabrication of a barrier bilayer of TaN/Ta. A specific recipe derived from the ranges of TABLE 1 is summarized in TABLE 2.

TABLE 2

| | TaN | Ta | Etch | Flash |
|---|---|---|---|---|
| Time (s) | | | | |
| DC Power (kW) | | 15 | 4 | 15-40 |
| Bias Power (kW) | | 0.2 | 0.7 | 0.2 |
| RF Coil Power (kW) | | 0 | 2 | 0 |
| DC Coil Power (kW) | | 0 | 0.75 | 0 |
| TIM Curr. (A) | | 0 | −1.75 | 0 |
| TOM Curr. (A) | | 0 | 0 | 0 |
| BIM Curr. (A) | | 19 | 21 | 19 |
| BOM Curr. (A) | | −19 | −21 | −19 |

These recipes differ from Gung's preferred recipe by not only the use of a TIM current during etching but also by a higher target power during etching, lower bias power during both deposition and etching, and increased RF coil power during etching.

Another recipe with ranges is summarized in TABLE 3.

TABLE 3

| | | | |
|---|---|---|---|
| TaN | Ta | Etch | Flash |

| | | | |
|---|---|---|---|
| Time (s) | | | |
| DC Power (kW) | 15-40 | 0-5 | 15-40 |
| Bias Power (kW) | 0-0.8 | 0.3-1 | 0-0.8 |
| RF Coil Power (kW) | 0 | 1-2.5 | 0 |
| DC Coil Power (kW) | 0 | 0-1 | 0 |
| TIM Curr. (A) | 0 | 0 | 0 |
| TOM Curr. (A) | 0 | −2-(−5) | 0 |
| BIM Curr. (A) | 19 | 15-21 | 19 |
| BOM Curr. (A) | −19 | −15-(−21) | −19 |
| Ar (sccm) | 4 | 10 | 4 |
| N₂ (sccm) | 0 | 0 | 0 |
| Magnet Position | OUT | OUT | OUT |
| Pressure (mTorr) | | | |

This recipe is principally distinguished from that of TABLE 1 by the use of TOM current rather than TIM current. The TOM current has to be higher than the functionally similar TIM current since its coil is further away from the chamber wall.

It has been found that the polarity of the TIM current relative to those of the BIM and BOM currents is relatively unimportant in reducing the sidewall asymmetry.

The ion steering has been described primarily with reference to sputter etching using argon ions. However, ion steering can also be applied to sputter deposition if there is a fairly high fraction of metal ions, such as can be achieved with tantalum.

Although the invention has been developed for barrier deposition of tantalum, other barrier materials such as ruthenium, ruthenium/tantalum, tungsten, titanium and their nitrides may be used with the invention. Furthermore, many of same angular considerations and sidewall asymmetry apply to sputter deposition of the copper seed layer in which very thin but continuous sidewall coverage is desirable. A copper sputter reactor can be equipt with two or more auxiliary electromagnets. The currents through the electromagnets are adjusted to produce the desired sidewall coverage, particularly at the wafer edge. Sidewall uniformity with reasonably high deposition rates can be obtained by varying the electromagnet currents to alternately produce an inward tapering and an outward tapering magnetic field at the wafer surface so that the copper ions successively hit opposed sidewalls. Copper can be sputtered with a relatively high fraction of copper ions so that the directional control of the sputter deposition is more greatly influenced.

Thus the invention provides for better control of the sputter/etch characteristics of thin layers barrier materials or of other materials such as copper in the complex geometries to which they are applied.

1. A method of sputter depositing metal containing material onto a substrate containing holes with sidewalls, comprising the steps of:
positioning the substrate in a plasma sputter reactor arranged about a central axis and including a target comprising metal and at least two electromagnets wrapped around side walls of a chamber of the sputtering the metal from the reactor including a fraction of ions of the metal; and
adjusting the currents supplied to the electromagnets to control a direction at which the ions strike the substrate.

2. The method of claim 1, wherein the currents are adjusted so that the ions strike a peripheral region of the substrate along a inclined direction toward the central axis.

3. The method of claim 1, wherein the adjusting step includes:
a first sub-step of adjusting the currents so that the ions strike a peripheral region of the substrate along a first inclined direction toward the central axis; and
a second sub-step of adjusting the currents so that the ions strike a peripheral region of the substrate along a second inclined direction towards the central axis.

4. The method of claim 1, wherein the electromagnets include first and second electromagnets of different radii disposed in a first plane perpendicular to the central axis and the adjusting step supplies opposed currents of unequal magnitudes to the first and second electromagnets.

5. The method of claim 1, wherein the electromagnets include first and second electromagnets of different radii disposed in a first plane perpendicular to the central axis and a third electromagnet disposed in a second plane displaced from and parallel to the first plane and wherein the adjusting step supplies opposed first and second currents to the first and second electromagnets respectively and a third current to the third electromagnet.

6. The method of claim 1, further comprising:
an RF inductive coil disposed around the central axis; and
a source of argon supplied into the chamber during the adjusting step.

7. The method of claim 1, wherein the material comprises a barrier material.

8. The method of claim 7, wherein the barrier material comprises tantalum.

9. The method of claim 1, wherein the material comprises copper.

10. A method of processing a substrate in a plasma sputter reactor including a sputter target, a support within a vacuum chamber arranged about a central axis and having an RF coil and at least two electromagnets wrapped around the central axis, comprising the steps of:
admitting argon into the chamber;
powering the RF coil with sufficient RF energy to excite the argon into a plasma; and
adjusting an amount of current delivered to the electromagnets to control an incidence angle of the argon ions onto the substrate.

11. The method of claim 10, wherein said two electromagnets comprise first and second electromagnets wrapped about the central axis in a first plane at two different radii and wherein the adjusting step causes unequal magnitudes of and opposite polarities of current to be delivered to the two electromagnets.

12. The method of claim 10, wherein said two electromagnets comprise first and second electromagnets wrapped about the central axis in a common plane at two different radii and further comprise a third electromagnet wrapped about the central axis in a second plane displaced along the central axis from the first plane and wherein the adjusting step causes opposite polarities of current to be delivered to the first and second electromagnets and further causes current to be delivered to the third electromagnet.

13. The method of claim 12, wherein the adjusting step causes equal magnitudes of current to be delivered to the first and second electromagnets.

14. A method of sputter etching a barrier layer of tantalum or tungsten over copper, comprising the steps of:
exciting a plasma including argon in a vacuum chamber containing a pedestal electrode supporting a substrate including a barrier layer comprising barrier material selected from group consisting of tantalum and tungsten overlying a copper layer; and
biasing the pedestal electrode to create a self-bias voltage thereon of no more than 65V to attract argon ions to the substrate.

15. The method of claim 14, wherein the substrate includes hole covered with the barrier layer and the copper layer underlies the barrier layer at a bottom of the hole, further comprising:
a preceding step of biasing the pedestal electrode to create a self-bias voltage greater than 65V; and
changing the self-bias voltage to no more than 65V after the barrier layer is broken through at the bottom of the hole.
